(19) United States
(12) Patent Application Publication
(10) Pub. No.: US 2025/0089465 A1
(43) Pub. Date: Mar. 13, 2025

(54) DISPLAY PANEL AND DISPLAY DEVICE

(71) Applicants: Mianyang HKC Optoelectronics Technology Co., Ltd., Mianyang (CN); HKC CORPORATION LIMITED, Shenzhen (CN)

(72) Inventors: Yao LI, Mianyang (CN); Lidan Ye, Mianyang (CN)

(21) Appl. No.: 18/766,693

(22) Filed: Jul. 9, 2024

(30) Foreign Application Priority Data
Sep. 13, 2023 (CN) 202311183536.7

(51) Int. Cl. H10K 59/122; H10K 59/80

(52) U.S. Cl. CPC H10K 59/122; H10K 59/873

(57) ABSTRACT

A display panel and a display device are provided. A hanging portion is defined by a portion of a top structure extending from an upper surface of a body structure. The display panel further includes a supporting layer, a filling layer, and an encapsulation layer. The supporting layer covers a plurality of sub-pixels and an inner side wall of each of a plurality of conductive isolation structures to support the hanging portion and defines a recess. At least part of the filling layer is filled in the recess and is configured to encapsulate the recess and support the hanging portion. A dual support is provided by the supporting layer and the filling layer to the hanging portion and improves an overall strength of the plurality of conductive isolation structures. The encapsulation layer further provides an anti-etching protection to the plurality of sub-pixels.

### CROSS-REFERENCE TO RELATED APPLICATIONS

This application claims priority to Chinese Patent Application No. 202311183536.7, filed on Sep. 13, 2023 in the National Intellectual Property Administration of China, the contents of which are herein incorporated by reference in their entireties.

### TECHNICAL FIELD

The present disclosure relates to the field of display technology, and in particular to a display panel and a display device.

### BACKGROUND

In order to realize a high resolution ratio and a colorization of an OLED (Organic Light-Emitting Diode), and further address problems, such as a low resolution ratio of a cathode plate and a low yield rate of device manufacturing, a cathode isolation pillar structure is introduced in a practical study. That is, instead of applying a metallic mask plate during the device manufacturing, an insulated partition wall is prepared on a substrate before an organic thin film and a metallic cathode being evaporated, thereby separating different pixels in the device and realizing a pixel array.

The cathode isolation pillar structure includes a conductive structure and an insulation structure connected to a cathode through a lap joint. Since a portion of the insulation structure hangs, a film layer of the hanging portion tends to peel or collapse during encapsulation, resulting in the cathode being punctured by the fractured film layer and affecting a connection consistency across an entire surface of the cathode.

### SUMMARY OF THE DISCLOSURE

The present disclosure may provide a display panel and a display device, in order to address a technical problem of a film layer peeling or collapsing during an encapsulation process in the related art.

In order to address the technical problem above, a first technical solution provided by the present disclosure provides a display panel and the display panel includes the following: a driving substrate, a pixel defining layer, a plurality of conductive isolation structures, a plurality of sub-pixels, a supporting layer, a filling layer, and an encapsulation layer. The pixel defining layer is disposed on the driving substrate and extends from the driving substrate to define a plurality of pixel accommodating areas. The plurality of conductive isolation structures are disposed on the pixel defining layer and surround an upper surface of each of the plurality of pixel accommodating areas. Each of the plurality of conductive isolation structures includes a body structure and a top structure that is disposed on an upper surface of the body structure and shields the body structure. A hanging portion is defined by a portion of the top structure extending from the upper surface of the body structure. The plurality of sub-pixels are disposed in the plurality of pixel accommodating areas. The supporting layer covers the plurality of sub-pixels and an inner side wall of each of the plurality of conductive isolation structures to support the hanging portion, defines a recess, and includes an alumina-based ceramic thin film. At least part of the filling layer is filled in the recess and is configured to encapsulate the recess and support the hanging portion. The encapsulation layer is disposed on a side of the filling layer away from the pixel defining layer and at least covers the filling layer.

In order to address the technical problem above, a second technical solution provided by the present disclosure provides a display device that includes the display panel above.

### BRIEF DESCRIPTION OF THE DRAWINGS

In order to illustrate the technical solutions in the embodiments of the present disclosure more clearly, the following is a brief introduction of the drawings associated with the description of the embodiments. It is obvious that the drawings described as follows are only for some of the embodiments of the present disclosure. For a person of ordinary skills in the art, other drawings may be obtained based on the following drawings without creative work.

FIG. 1 is a schematic view of a display panel according to the first embodiment of the present disclosure.

FIG. 2 is a schematic view of a display panel according to the second embodiment of the present disclosure.

FIG. 3 is a schematic view of a display panel according to the third embodiment of the present disclosure.

In the figure:
10, driving substrate; 20, pixel defining layer; 210, pixel accommodating area; 30, sub-pixel; 31, anode; 32, light-emitting layer; 33, cathode; 40, conductive isolation structure; 41, body structure; 411, conductive structure; 412, intermediate structure; 42, top structure; 421, hanging portion; 50, encapsulation layer; 60, supporting layer; 610, recess; 70, filling layer; 80, organic encapsulation layer; 90, inorganic encapsulation layer.

### DETAILED DESCRIPTION

In conjunction with the drawings, the implementations according to the embodiments of the present disclosure are described in details as follows.

In the following description, for the purpose of illustrations rather than limitations, specific details such as particular system structures, interfaces, and techniques are presented in order to thoroughly understand the embodiments of the present disclosure.

The technical solutions in the embodiments of the present disclosure are clearly and thoroughly described below in conjunction with the drawings in the embodiments of the present disclosure. Obviously, the embodiments described are merely a part of the embodiments, rather than all the embodiments, of the present disclosure. Based on the embodiments of the present disclosure, all other embodiments obtained by a person of ordinary skills in the art without creative work fall within the scope of protection of the present disclosure.

The terms “first”, “second”, and “third” in the present disclosure are used for descriptive purposes only and may not be understood to indicate or imply relative importance or implicitly specify the number of technical features indicated. Thus, a feature defined with the terms “first”, “second”, and “third” may, either explicitly or implicitly, indicate that at least one such feature is provided. In the description of the present disclosure, “plurality” means at least two, e.g., two, three, and etc., unless otherwise explicitly and specifically indicated. All directional indications (e.g., top, bottom, left, right, front, and back . . . ) in the embodiments of the present disclosure are only used to explain the relative positional relationship, movement, and etc. between the components in a particular positioning (as illustrated in the drawings), and the directional indications may be changed accordingly given the positioning being changed. In addition, the terms “including”, “having” and any variations thereof are intended to indicate a non-exclusive inclusion. For example, a process, method, system, product or apparatus including a series of steps or units is not limited to the listed steps or units, but optionally may further include steps or units that are not listed, or other steps or units that are inherent to the process, method, product or apparatus.

References to “embodiment” in the specification of the present disclosure indicate that a particular feature, structure, or characteristics described in conjunction with the embodiment may be provided in one or more embodiments of the present disclosure. The “embodiment” appeared across the specification refers to neither necessarily the identical embodiment, nor a separate or alternate embodiment that is mutually exclusive with other embodiments. It can be understood by the person of ordinary skills in the art, both explicitly and implicitly, that the embodiments described herein may be combined with other embodiments.

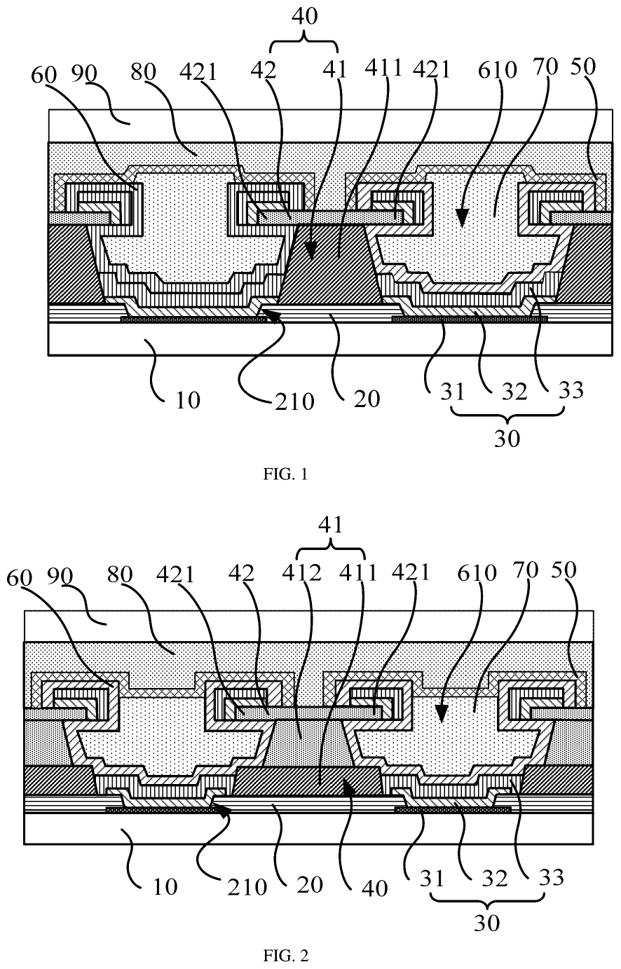

As illustrated in FIG. 1, FIG. 1 is a schematic view of a display panel according to the first embodiment of the present disclosure.

Some embodiments of the present disclosure provide a display panel. The display panel includes a driving substrate 10, a pixel defining layer 20, a plurality of sub-pixels 30, and a plurality of conductive isolation structures 40. The pixel defining layer 20 is disposed on the driving substrate 10. The pixel defining layer 20 extends from the driving substrate 10 to define a plurality of pixel accommodating areas 210. The plurality of conductive isolation structures 40 are disposed on the pixel defining layer 20 and encircles or surrounds an upper surface of each of the plurality of pixel accommodating areas 210. Each of the plurality of conductive isolation structures 40 includes a body structure 41 and a top structure 42 that is disposed on an upper surface of the body structure 41 and shields the body structure 41. A hanging portion 421 is defined by a portion of the top structure 42 that extends from the upper surface of the body structure 41. The plurality of sub-pixels 30 are disposed in the plurality of pixel accommodating areas 210. The display panel further includes a supporting layer 60, a filling layer 70, and an encapsulation layer 50. The supporting layer 60 covers the plurality of sub-pixels 30 and an inner side wall of each of the plurality of conductive isolation structures 40 to support the hanging portion 421, and a recess 610 is encircled and defined by the supporting layer 60. At least part of the filling layer 70 is filled in the recess 610 to encapsulate the recess 610 and support the hanging portion 521. The encapsulation layer 50 is disposed on a side of the filling layer 70 away from the pixel defining layer 20 and at least covers the filling layer 70. Some embodiments of the present disclosure provide a dual support to the hanging portion 521 and improve an overall strength of the plurality of conductive isolation structures 40 through disposing the supporting layer 60 on the inner side wall of each of the plurality of conductive isolation structures 40 and disposing the filling layer 70 in the recess 610 encircled or defined by the supporting layer 60. In this way, some embodiments of the present disclosure avoid a lapped joint between a cathode 33 and a corresponding one of the plurality of conductive isolation structures 40 from fracturing and affecting a connection consistency across an entire surface of the cathode 33, as a result of the cathode 33 below the hanging portion 421 being punctured by a film layer of the hanging portion 421 that peels or collapses during an encapsulation the display panel.

The driving substrate 10 is configured to drive the plurality of sub-pixels 30 to emit light.

Each of the plurality of sub-pixels 30 includes an anode 31, a light-emitting layer 32, and the cathode 33 arranged in stack. In some embodiments, the light-emitting layer 32 may be an organic light-emitting layer. The cathode 33 is disposed between the light-emitting layer 32 and the supporting layer 60. There is more than one sub-pixel 30 and each of the plurality of sub-pixels 30 corresponds to one color pixel. There is more than one pixel accommodating area 210 and each of the plurality of pixel accommodating areas 210 accommodates at least one of the plurality of sub-pixels 30.

An arrangement of the plurality of sub-pixels 30 is not limited by the present disclosure and may be determined based on actual needs. The present disclosure is illustrated as follows by taking any adjacent two of the plurality of sub-pixels 30 as example.

In the present embodiment, each of the plurality of pixel accommodating areas 210 accommodates a corresponding one of the plurality of sub-pixels 30.

The plurality of conductive isolation structures 40 are configured to isolate the plurality of sub-pixels 30 from each other. In some embodiments, the light-emitting layer 32 of each of the plurality of sub-pixels 30 is isolated by a corresponding one of the plurality of conductive isolation structures 40, and the cathode 33 of each of the plurality of sub-pixels 30 of different colors is isolated by a corresponding one of the plurality of conductive isolation structures 40, thereby avoiding a problem of pixel crosstalk. In addition, the cathode 33 of each of the plurality of sub-pixels 30 is conducted to a corresponding one of the plurality of conductive isolation structures 40 so that the plurality of conductive isolation structures 40 may be configured to connect the cathode 33 of each of the plurality of sub-pixels 30, thereby achieving a mesh connection among the cathodes 33 of the plurality of sub-pixels 30 and realizing a signal uniformity across the entire surface of the cathode 33.

The top structure 42 is disposed on the upper surface of the body structure 41 and shields the body structure 41. In other words, the top structure 42 is arranged in contact with the body structure 41 and an orthographic projection of the top structure 42 on the driving substrate 10 completely overlaps an orthographic projection of the body structure 41 on the driving substrate 10. The hanging portion 421 is arranged in suspension with respect to the body structure 41. When the light-emitting layer 32 and the cathode 33 are being evaporated, the cathode 33 may be configured to cover the light-emitting layer 32 by means of the hanging portion 421 changing an evaporation angle, thereby facilitating the cathode 33 to be arranged in contact with the body structure 41 and conducted to the body structure 41.

There is more than one conductive isolation structure 40 and any adjacent two of the plurality of conductive isolation structures 40 share a common side so that distances between any adjacent two of the plurality of sub-pixels 30 are the same, thereby facilitating a display uniformity. In the present embodiment, each of the plurality of conductive isolation structures 40 has a ring-shaped rectangular structure, and the plurality of conductive isolation structures 40 are arranged in array. Along a row direction or a column direction of the plurality of conductive isolation structures 40, any adjacent two of the plurality of conductive isolation structures 40 share a common side.

In the present embodiment, the body structure 41 includes a conductive structure 411. A side wall of the conductive structure 411 and the hanging portion 421 are arranged to be inclined to each other and an angle of inclination between a lower surface of the hanging portion 421 and the side wall of the conductive structure 411 is less than 90 degrees. In other words, along a direction perpendicular to the driving substrate 10, a vertical cross-section of the side wall of the conductive structure 411 is a trapezoid and an area of a horizontal cross-section of the side wall of the conductive structure 411 reduces as being closer to the top structure 42.

The following description takes any adjacent two of the plurality of conductive isolation structures 40 as example. It is to be understood that, some embodiments of the present disclosure may include more than two conductive isolation structures 40.

The top structure 42 includes at least one of SiO2, SiNx, and SiNO. In some embodiments, the top structure 42 may include other insulated materials. X is a non-zero natural number.

It is to be understood that, since the body structure 41 is configured to support the top structure 42, a cross-sectional width of an end of the body structure 41 in contact with the top structure 42 (i.e., an upper surface of the conductive structure 411) along the direction perpendicular to the driving substrate 10 may not be too small; otherwise, the body structure 41 may be unable to support the top structure 42. Therefore, the cross-sectional width of the end of the body structure 41 in contact with the top structure 42 needs to satisfy a certain value. In case where the cross-sectional width of the end of the body structure 41 in contact with the top structure 42 is a fixed value, if the angle of inclination between the lower surface of the hanging portion 421 and the side wall of the conductive structure 411 increases, the support provided by the conductive structure 411 to the top structure 42 may be better, and a joint between the conductive structure 411 and cathode 33 may be less likely to fracture. However, if the side wall of the conductive structure 411 is steeper, a film formation on the supporting layer 60 that covers an inner side wall of the conductive structure 411 may be more difficult, and thus an adhesion and a strength of the supporting layer 60 may be reduced.

Some embodiments of the present disclosure instead provide the dual support to the hanging portion 421 through disposing the supporting layer 60 on the inner side wall of each of the plurality of conductive isolation structures 40 and disposing the filling layer 70 in the recess 610 encircled or defined by the supporting layer 60. In this way, the supporting layer 60 and the filling layer 70 are configured to share a support force to the hanging portion 421 with the body structure 40, so that the cross-sectional width of the end of the body structure 41 in contact with the top structure 42, along the direction perpendicular to the driving substrate 10, may be reduced compared to that of a case where the supporting layer 60 and the filling layer 70 are absent. In this way, the angle of inclination between the lower surface of the hanging portion 421 and the side wall of the conductive structure 411 may be reduced, the side wall of the conductive structure 411 may be less steep, the film formation on the supporting layer 60 that covers the inner side wall of the conductive structure 411 may be less difficult, and the strength of the supporting layer 60 as well as the adhesion of supporting layer 60 on the side wall of the conductive structure 411 may be greatly improved. In addition, since an area of the end of the body structure 41 in contact with the top structure 42 is reduced, a width of the hanging portion 421 may be greater than a width of an end of the conductive structure 411 close to the top structure 42, thereby increasing a controllability over the evaporation angle of evaporating the light-emitting layer 32 and the cathode 33.

The cathode 33 is arranged in contact with the conductive structure 411 and conducted to the conductive structure 411. In other words, the cathode 33 is conducted to the conductive structure 411 through the body structure 41.

The supporting layer 60 covers the inner side wall of the conductive structure 411. That is, the supporting layer 60 covers a side wall of the body structure 41, a side wall of the top structure 42, and the lower surface of the hanging portion 421.

The supporting layer 60 further covers a part of an upper surface of the top structure 42. In other words, the supporting layer 60 extends along a side wall of each of the plurality of conductive isolation structures 40 to encircle and define the recess 610, and the supporting layer 60 further extends from the inner side wall of each of the plurality of conductive isolation structures 40 to the part of the upper surface of the top structure 42. The encapsulation layer 50 covers the supporting layer 60 on the upper surface of the top structure 42.

A part of the supporting layer 60 that covers the inner side wall of each of the plurality of conductive isolation structures 40 is defined to be a side wall of the recess 610 and another part of the supporting layer 60 that covers the plurality of sub-pixels 30 is defined to be a bottom wall of the recess 610. The recess 610 is pot-shaped and an opening of the recess 610 faces a side away from the driving substrate 10.

It is to be understood that, when the cathode 33 and the light-emitting layer 32 are being evaporated onto an upper surface of the anode 31, a part of the light-emitting layer 32 and a part of the cathode 33 may be stacked on the side wall of the top structure 42 and the upper surface of the top structure 42 in sequence. The supporting layer 60 covers not only the part of the upper surface of the top structure 42, but also the cathode 33 on the upper surface of the top structure 42, the cathode 33 on the side wall of the top structure 42, the light-emitting layer 32 on the upper surface of the top structure 42, and the light-emitting layer 32 on the side wall of the top structure 42.

The supporting layer 60 includes an alumina-based ceramic thin film. The supporting layer 60 is highly transparent so that the supporting layer 60 may support the hanging portion 421 without blocking light emitted by the plurality of sub-pixels 30, thereby not affecting a normal display of the display panel. In addition, the supporting layer 60 has insulation and high strength to effectively resist stress in the subsequent manufacturing. A film layer of the supporting layer 60, because of the high strength and a high toughness, is unlikely to fracture and thus may effectively support the hanging portion 421 to protect the cathode 33. A thickness of the supporting layer 60 is 1-2 μm.

The filling layer 70 may include an organic acrylic material or other insulating materials, which is not limited herein and may be determined based on actual needs.

In the present embodiment, an upper surface of the filling layer 70 is slightly higher than a surface of a side of the supporting layer 60 located on the upper surface of the top structure 42 that is away from the pixel defining layer 20. In this way, a height difference between the upper surface of the filling layer 70 and the surface of the side of the supporting layer 60 located on the upper surface of the top structure 42 that is away from the pixel defining layer 20 is ensured to be small, thereby effectively avoiding a film layer of the encapsulation layer 50 from fracturing; in addition, the filling layer 70 may completely fill a space below the hanging portion 421 to support the hanging portion 421. That is, a part of the filling layer 70 is located in the recess 610.

In some embodiments, the upper surface of the filling layer 70 is higher than the surface of the side of the supporting layer 60 located on the upper surface of the top structure 42 that is away from the pixel defining layer 20 and the height difference between the upper surface of the filling layer 70 and the surface of the side of the supporting layer 60 located on the upper surface of the top structure 42 that is away from the pixel defining layer 20 is less than 5 μm. In case where the height difference is too great, the film layer of the encapsulation layer 50 tends to fracture when the encapsulation layer 50 is being evaporated onto the upper surface of the filling layer 70 because a climbing height of the encapsulation layer 50 is too great, thereby resulting in a failure to achieve a desired protection against etching.

It is to be understood that, during an actual preparation of the filling layer 70, it may be difficult to guarantee that the upper surface of the filling layer 70 and the surface of the side of the supporting layer 60 located on the upper surface of the top structure 42 that is away from the pixel defining layer 20 are flush with each other. In this way, through arranging the upper surface of the filling layer 70 to be slightly higher than the surface of the side of the supporting layer 60 located on the upper surface of the top structure 42 that is away from the pixel defining layer 20, the film layer of the encapsulation layer 50 that covers the upper layer of the filling layer 70 may be flatter, which ensures that an etching during a subsequent deposition of the light-emitting layer 32 and the cathode 33 of each of the plurality of sub-pixels 30 of other colors on the encapsulation layer 50 is more thorough, thereby avoiding any residual of the plurality of sub-pixels 30 of other colors on the encapsulation layer 50.

Moreover, the filling layer 70 covers a part of the surface of the side of the supporting layer 60 located on the upper surface of the top structure 42 that is away from the pixel defining layer 20, instead of the entire surface of the side of the supporting layer 60 located on the upper surface of the top structure 42 that is away from the pixel defining layer 20, thereby avoiding the encapsulation layer 50 located on the top structure 42 from fracturing due to an excessive stacking height of the film layer located on the side of the top structure 42 away from the driving substrate 10, as well as saving materials.

It is to be noted that, since neither the supporting layer 60 nor the filling layer 70 alone can provide adequate support to the hanging portion 421, it is necessary to combine the supporting layer 60 and the filling layer 70 to support the hanging portion 421. In other words, some embodiments of the present disclosure meet a support requirement for the hanging portion 421 through providing the dual support with the supporting layer 60 and the filling layer 70.

The encapsulation layer 50 is configured to provide an anti-etching protection to the plurality of sub-pixels 30 during the manufacturing of the display panel. The encapsulation layer 50 includes a non-conductive inorganic material. In some embodiments, the encapsulation layer 50 includes a silicon-involved inorganic material, e.g., a SiNx-type inorganic material, where x is a non-zero natural number.

The encapsulation layer 50 covers the upper surface of the filling layer 70 and the supporting layer 60 located on a side of the upper surface of the top structure 42 that is away from the driving substrate 10 to provide the anti-etch protection and encapsulation for the supporting layer 60, the filling layer 70, and the plurality of sub-pixels 30.

It is to be understood that, in the related art, after the plurality of sub-pixels 30 of one color are manufactured and before the plurality of sub-pixel 30 of other colors are manufactured, a space between side walls of adjacent two of the plurality of conductive isolation structures 40 is empty. In this way, during a subsequent coating and etching for the light-emitting layer 32 and the cathode 33 of the plurality of sub-pixels 30 of other colors, the hanging portion 421 of the top structure 42 tends to fracture due to multiple layers of film stacking. Besides, a structural design of the plurality of conductive isolation structures 40 may cause the side wall of each of the plurality of conductive isolation structures 40 to be uneven and have a concave structure (i.e., a joint between the lower surface of the hanging portion 421 and the side wall of the conductive structure 411), which is likely to adversely affect a light emission of the plurality of sub-pixels 30 due to the residue of the light-emitting layer 32 and cathode 33 of the plurality of sub-pixels 30 of other colors accumulating between the side walls of adjacent two of the plurality of conductive isolation structures 40. In addition, the uneven side wall of each of the plurality of conductive isolation structures 40 and a climbing at the joint between the cathode 33 and the conductive structure 411 may cause the film layer of the encapsulation layer 50 that covers the plurality of sub-pixels 30 and the side wall of each of the plurality of conductive isolation structures 40 to be uneven, thereby leading to multiple interfaces and fracture surfaces thereon in the related art. In this way, the brittleness of the film layer of the encapsulation layer 50 may result in film quality problems, such as a film layer fracture or pinhole, which directly weakens the subsequent anti-etching protection and an ability to encapsulate the cathode 33, thereby affecting a service life of the device.

In some embodiments of the present disclosure, the space between the side walls of adjacent two of the plurality of conductive isolation structures 40 (i.e., the recess 610) is filled with the filling layer 70, and the supporting layer 60 is arranged to adequately support the hanging portion 421. In this way, a load capacity of the hanging portion 421 may be greatly improved, thereby avoiding the film layers from fracturing during a subsequent film stacking and avoiding the residue of the light-emitting layer 32 and cathode 33 of the plurality of sub-pixels 30 of other colors from accumulating between the side walls of adjacent two of the plurality of conductive isolation structures 40. In addition, in the related art, the encapsulation layer 50 covers the inner side wall of each of the plurality of conductive isolation structures 40 and the anti-etching protection to the plurality of sub-pixels 30 is only performed by the encapsulation layer 50; therefore, a performance of the anti-etching protection by the encapsulation layer 50 heavily depends on the film quality of the covers layer 50. However, compared to the supporting layer 60, the encapsulation layer 50 that is made of an SiNx-type inorganic material is inferior in terms of the toughness and strength. That is, the supporting layer 60 in some embodiments of the present disclosure is disposed on the inner side wall of each of the plurality of conductive isolation structures 40 to improve the overall strength of the plurality of conductive isolation structures 40 and the ability to encapsulate the plurality of sub-pixels 30. Furthermore, the dual support provided by the supporting layer 60 and the filling layer 70 to the hanging portion 421 may not only enhance the display effect of the display panel but also avoid the film layer from peeling or collapsing.

It is to be noted that, since neither the filling layer 70 nor the supporting layer 60 is able to perform the anti-etching protection, in the display panel according to some embodiments of the present disclosure, the encapsulation layer 50 is required to be disposed on the side of the filling layer 70 away from the pixel defining layer 20 and to cover at least the upper surface of the filling layer 70, thereby ensuring that the encapsulation layer 50 performs the anti-etching protection to protect and encapsulate the plurality of sub-pixels 30.

In other words, the supporting layer 60 and the filling layer 70 according to some embodiments of the present disclosure cooperate to realize the support of the hanging portion 421. The supporting layer 60, the filling layer 70, and the encapsulation layer 50 cooperate to realize the anti-etching protection to the plurality of sub-pixels 30 and the encapsulation of the plurality of sub-pixels 30.

It is to be understood that, in some embodiments of the present disclosure, the height difference between the upper surface of the filling layer 70 and the surface of the side of the supporting layer 60 located on the upper surface of the top structure 42 that is away from the pixel defining layer 20 is not too great. In this way, compared to the related art that requires the encapsulation layer 50 to cover the side wall of each of the plurality of conductive isolation structures 40, the surface of the encapsulation layer 50 in the present disclosure is relatively flat, which allows an etching surface of the encapsulation layer 50 to be flatter and leads to a more thorough etching during the subsequent manufacturing of the plurality of sub-pixels 30 of other colors, and avoids the residues of the plurality of sub-pixels 30 of other colors from accumulating on the encapsulation layer 50. In addition, since the film layer of the encapsulation layer 50 in some embodiments of the present disclosure is relatively flat, the film quality, the film formation, and the encapsulation performance of the encapsulation layer 50 may be greatly improved compared to the related art.

The display panel further includes an organic encapsulation layer 80 and an inorganic encapsulation layer 90 stacked on a side of the encapsulation layer 50 away from the pixel defining layer 20 in sequence. A material of the organic encapsulation layer 80 and a material of the inorganic encapsulation layer 90 are not limited herein, and may be determined based on actual needs.

It is to be noted that in some embodiments of the present disclosure, an upper surface refers to a surface of a side that is away from the driving substrate 10 and a lower surface refers to a surface of a side that is close the driving substrate 10.

As illustrated in FIG. 1 and FIG. 2, FIG. 2 is a schematic view of a display panel according to the second embodiment of the present disclosure.

In the present disclosure, a structure of a display panel provided in the second embodiment is essentially or substantially identical to a structure of the display panel provided in the first embodiment, except for a difference in that the body structure 41 further includes an intermediate structure 412 disposed between the conductive structure 411 and the top structure 42. The upper surface of the filling layer 70 is not lower than (i.e., higher than or at the same level with) a surface of a side of the supporting layer 60 disposed on the lower surface of the hanging portion 421 that is close to the pixel defining layer 20 and is not higher than (i.e., lower than or at the same level with) a surface of a side of the supporting layer 60 disposed on the upper surface of the top structure 42 that is away from the pixel defining layer 20.

In the present embodiment, the body structure 41 includes the conductive structure 411 and the intermediate structure 412 disposed between the conductive structure 411 and the top structure 42. A side wall of the intermediate structure 412 and the hanging portion 421 are arranged to be inclined to each other and an angle of inclination between a lower surface of the hanging portion 421 and the side wall of the intermediate structure 412 is less than 90 degrees. That is, along the direction perpendicular to the driving substrate 10, a vertical cross-section of the side wall of the intermediate structure 421 is a trapezoid and a horizontal cross-section of the side wall of the intermediate structure 421 reduces as being closer to the top structure 42. The cathode 33 is arranged in contact with the conductive structure 411 and conducted to the conductive structure 411.

A material of the intermediate structure 412 and a material of the top structure 42 may or may not be the same. In the present embodiment, the intermediate structure 412 and top structure 42 are made of the same material. The top structure 42 includes at least one of SiO2, SiNx, and SiNO, where x is a non-zero natural number. In some embodiments, the top structure 42 may be made of other insulating materials. Differences in etching rates of distinct materials are utilized to construct the shape of the intermediate structure 412 and the shape of the top structure 42.

Similarly, as described above in the present embodiment, along the direction perpendicular to the driving substrate 10, the cross-sectional width of the end of the body structure 41 in contact with the top structure 42 may be reduced compared to that of a case where the supporting layer 60 and the filling layer 70 are absent. In this way, the angle of inclination between the lower surface of the hanging portion 421 and the side wall of the intermediate structure 411 may be reduced, the side wall of the intermediate structure 412 may be less steep, and the film formation on the supporting layer 60 that covers the side wall of the intermediate structure 412 may be less difficult, thereby greatly improving the strength of the supporting layer 60 and the adhesion of the supporting layer 60 on the side wall of the intermediate structure 412. In addition, since an area of an end of the intermediate structure 412 in contact with the top structure 42 is reduced, a width of the hanging portion 421 may be greater than a width of the end of the intermediate structure 412 close to the top structure 42, thereby increasing the controllability over the evaporation angle of evaporating the light-emitting layer 32 and the cathode 33.

The upper surface of the filling layer 70 is not lower than (i.e., higher than or at the same level with) the surface of the side of the supporting layer 60 disposed on the lower surface of the hanging portion 421 that is close to the pixel defining layer 20 and is not higher than (i.e., lower than or at the same level with) the surface of the side of the supporting layer 60 disposed on the upper surface of the top structure 42 that is away from the pixel defining layer 20; i.e., the supporting layer 60 is disposed on the upper surface of the top structure 42, and the upper surface of the filling layer 70 is not higher than (i.e., lower than or at the same level with) the surface of the supporting layer 60 located at the side away from the pixel defining layer 20. In other words, the upper surface of the filling layer 70 is higher than or at the same level as the surface of the side of the supporting layer 60 disposed on the lower surface of the hanging portion 421 that is close to the pixel defining layer 20. In this way, the upper surface of the filling layer 70 is arranged in contact with the surface of the side of the supporting layer 60 disposed on the lower surface of the hanging portion 421 that is close to the pixel defining layer 20, thereby ensuring that the space under the hanging portion 421 is completely filled by the filling layer 70 to support the hanging portion 421. The upper surface of the filling layer 70 is lower than or at the same level as the surface of the side of the supporting layer 60 disposed on the upper surface of the top structure 42 that is away from the pixel defining layer 20, thereby avoiding the filling layer 70 from being too thick to ensure the normal manufacturing of other film layers in subsequent.

In the present embodiment, the upper surface of the filling layer 70 is not lower than (i.e., higher than or at the same level with) the surface of the side of the supporting layer 60 disposed on the lower surface of the hanging portion 421 that is close to the pixel defining layer 20 and is slightly lower than the surface of the side of the supporting layer 60 disposed on the upper surface of the top structure 42 that is away from the pixel defining layer 20. In this way, the height difference between the upper surface of the filling layer 70 and the surface of the side of the supporting layer 60 disposed on the upper surface of the top structure 42 that is away from the pixel defining layer 20 is not too great so that the filling layer 70 may not only support the hanging portion 421, but also avoid the film layer of the encapsulation layer 50 from fracturing.

In the present disclosure, the display panel provided by the second embodiment may realize the same effect as the display panel provided by the first embodiment. Besides, compared with the display panel provided by the first embodiment of the present disclosure, the intermediate structure 412 is disposed between the conductive structure 411 and the top structure 42 according to the second embodiment, thereby further reducing the height of the conductive structure 411 and facilitating the cathode 33 to be connected to the conductive structure 411 through the lap joint.

It is to be understood that, the plurality of conductive isolation structures 40 may be constructed in other structures, as long as the top structure 42 shields the body structure 41 and a portion of the top structure 42 is arranged in suspension with respect to the body structure 41 to form the hanging portion 421.

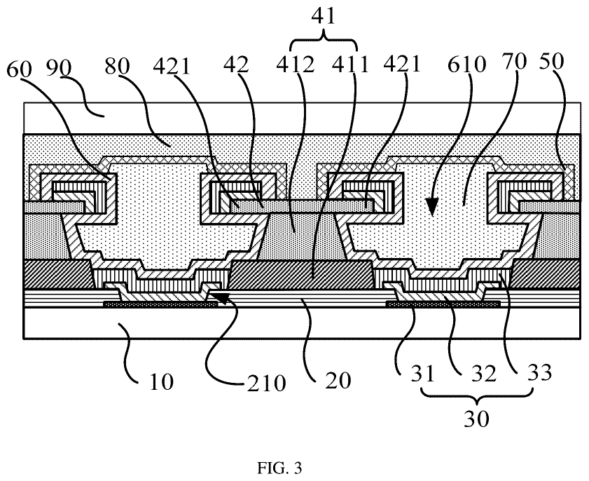

As illustrated in FIG. 2 and FIG. 3, FIG. 3 is a schematic view of a display panel according to the third embodiment of the present disclosure.

In the present disclosure, a structure of a display panel provided in the third embodiment is essentially or substantially identical to the structure of the display panel provided in the second embodiment, except for a difference in that the upper surface of the filling layer 70 is slightly higher than the surface of the side of the supporting layer 60 disposed on the upper surface of the top structure 42 that is away from the pixel defining layer 20.

In the present embodiment, the upper surface of the filling layer 70 is slightly higher than the surface of the side of the supporting layer 60 disposed on the upper surface of the top structure 42 that is away from the pixel defining layer 20, ensuring that the height difference between the upper surface of the filling layer 70 and the surface of the side of the supporting layer 60 disposed on the upper surface of the top structure 42 that is away from the pixel defining layer 20 is not too great, and thereby effectively avoiding the film layer of the encapsulation layer 50 from fracturing. In addition, the filling layer 70 is ensured to completely fill the space below the hanging portion 421 to support the hanging portion 421.

The present embodiment may realize the same effect as the display panel provided in the second embodiment of the present disclosure, and will not be further described herein. More details of the present embodiments may refer to the description above.

Some embodiments of the present disclosure provide a display device and the display device includes the display panel described above. The display panel according to some embodiments of the present disclosure is an OLED display panel.

In the above embodiments, the description of each embodiment has its own focus, and parts of an embodiment that are not described in detail may refer to relevant descriptions in other embodiments.

The above only describes the implementations of the present disclosure, and is not intended to limit the scope of protection of the present disclosure. Any equivalent structure or process alternations based on the specification of present application and the drawings, and their direct or indirect application in other related technical fields, are all similarly included in the scope of protection of the present disclosure.

What is claimed is:

1. A display panel, comprising:
a driving substrate;
a pixel defining layer, disposed on the driving substrate and extending from the driving substrate to define a plurality of pixel accommodating areas;
a plurality of conductive isolation structures, disposed on the pixel defining layer and surrounding an upper surface of each of the plurality of pixel accommodating areas; wherein each of the plurality of conductive isolation structures comprises a body structure and a top structure disposed on an upper surface of the body structure and shielding the body structure; a hanging portion is defined by a portion of the top structure extending from the upper surface of the body structure;
a plurality of sub-pixels, disposed in the plurality of pixel accommodating areas;
a supporting layer, covering the plurality of sub-pixels and an inner side wall of each of the plurality of conductive isolation structures to support the hanging portion, defining a recess, and comprising an alumina-based ceramic thin film;
a filling layer, at least part of the filling layer being filled in the recess and configured to encapsulate the recess and support the hanging portion; and
an encapsulation layer, disposed on a side of the filling layer away from the pixel defining layer and at least covering the filling layer.

2. The display panel according to claim 1, wherein the supporting layer further covers a part of an upper surface of the top structure and the encapsulation layer covers the supporting layer on the upper surface of the top structure.

3. The display panel according to claim 2, wherein an upper surface of the filling layer is higher than or at the same level with a surface of a side of the supporting layer on a lower surface of the hanging portion that is close to the pixel defining layer and is lower than or at the same level with a surface of a side of the supporting layer on an upper surface of the top structure that is away from the pixel defining layer.

4. The display panel according to claim 2, wherein the upper surface of the filling layer is slightly higher than the surface of the side of the supporting layer on the upper surface of the top structure that is away from the pixel defining layer.

5. The display panel according to claim 4, wherein a height difference between the upper surface of the filling layer and the surface of the side of the supporting layer on the upper surface of the top structure that is away from the pixel defining layer is less than 5 μm.

6. The display panel according to claim 4, wherein the supporting layer covers a part of the surface of the side of the supporting layer on the upper surface of the top structure that is away from the pixel defining layer.

7. The display panel according to claim 1, wherein the body structure comprises a conductive structure, a side wall of the conductive structure and the hanging portion are arranged to be inclined to each other, and an angle of inclination between a lower surface of the hanging portion and the side wall of the conductive structure is less than 90 degrees; or
the body structure comprises the conductive structure and an intermediate structure disposed between the conductive structure and the top structure, a side wall of the intermediate structure and the hanging portion are arranged to be inclined to each other, and an angle of inclination between the lower surface of the hanging portion and the side wall of the intermediate structure is less than 90 degrees.

8. The display panel according to claim 7, wherein each of the plurality of sub-pixels comprises an anode, a light-emitting layer, and a cathode arranged in stack; the cathode is disposed between the light-emitting layer and the supporting layer; the cathode is arranged in contact with the conductive structure and is conducted to the conductive structure.

9. The display panel according to claim 8, wherein the light-emitting layer of each of the plurality of sub-pixels is isolated by a corresponding one of the plurality of conductive isolation structures, and the cathode of each of the plurality of sub-pixels of different colors is isolated by a corresponding one of the plurality of conductive isolation structures.

10. The display panel according to claim 1, wherein a thickness of the supporting layer is 1-2 μm.

11. The display panel according to claim 1, wherein the display panel further comprises an organic encapsulation layer and an inorganic encapsulation layer stacked on a side of the encapsulation layer away from the pixel defining layer in sequence.

12. The display panel according to claim 1, wherein the top structure is arranged in contact with the body structure and an orthographic projection of the top structure on the driving substrate completely overlaps an orthographic projection of the body structure on the driving substrate; the hanging portion is arranged in suspension with respect to the body structure.

13. The display panel according to claim 1, wherein any adjacent two of the plurality of conductive isolation structures share a common side.

14. A display device, comprising a display panel, wherein the display panel comprises:
a driving substrate;
a pixel defining layer, disposed on the driving substrate and extending from the driving substrate to define a plurality of pixel accommodating areas;
a plurality of conductive isolation structures, disposed on the pixel defining layer and surrounding an upper surface of each of the plurality of pixel accommodating areas; wherein each of the plurality of conductive isolation structures comprises a body structure and a top structure disposed on an upper surface of the body structure and shielding the body structure; a hanging portion is defined by a portion of the top structure extending from the upper surface of the body structure;
a plurality of sub-pixels, disposed in the plurality of pixel accommodating areas;
a supporting layer, covering the plurality of sub-pixels and an inner side wall of each of the plurality of conductive isolation structures to support the hanging portion, defining a recess, and comprising an alumina-based ceramic thin film;
a filling layer, at least part of the filling layer being filled in the recess and configured to encapsulate the recess and support the hanging portion; and
an encapsulation layer, disposed on a side of the filling layer away from the pixel defining layer and at least covering the filling layer.

15. The display device according to claim 14, wherein the supporting layer further covers a part of an upper surface of the top structure and the encapsulation layer covers the supporting layer on the upper surface of the top structure.

16. The display device according to claim 14, wherein the body structure comprises a conductive structure, a side wall of the conductive structure and the hanging portion are arranged to be inclined to each other, and an angle of inclination between a lower surface of the hanging portion and the side wall of the conductive structure is less than 90 degrees; or
the body structure comprises the conductive structure and an intermediate structure disposed between the conductive structure and the top structure, a side wall of the intermediate structure and the hanging portion are arranged to be inclined to each other, and an angle of inclination between the lower surface of the hanging portion and the side wall of the intermediate structure is less than 90 degrees.

17. The display device according to claim 14, wherein a thickness of the supporting layer is 1-2 μm.

18. The display device according to claim 14, wherein the display panel further comprises an organic encapsulation layer and an inorganic encapsulation layer stacked on a side of the encapsulation layer away from the pixel defining layer in sequence.

19. The display device according to claim 14, wherein the top structure is arranged in contact with the body structure and an orthographic projection of the top structure on the driving substrate completely overlaps an orthographic projection of the body structure on the driving substrate; the hanging portion is arranged in suspension with respect to the body structure.

20. The display device according to claim 14, wherein any adjacent two of the plurality of conductive isolation structures share a common side.
